(19) United States
(12) Patent Application Publication
(10) Pub. No.: US 2022/0286125 A1
(43) Pub. Date: Sep. 8, 2022

(54) RECYCLING AND CLAMPING REFLECTED VOLTAGES IN CASCODE GAN HEMT DEVICES

(71) Applicant: GLC SEMI CONDUCTOR GROUP (SH) CO., LTD., Shanghai (CN)

(72) Inventors: Kuo-Chang Kao, Taoyuan City (TW); Chi-Ching Pu, Hsinchu County (TW); Shun-Min Yeh, Hsinchu City (TW)

(73) Assignee: GLC SEMI CONDUCTOR GROUP (SH) CO., LTD., Shanghai (CN)

(21) Appl. No.: 17/543,749

(22) Filed: Dec. 7, 2021

Related U.S. Application Data
(60) Provisional application No. 63/156,905, filed on Mar. 4, 2021.

(30) Foreign Application Priority Data
Aug. 2, 2021 (TW) 110128336

(51) Int. Cl. H03K 17/567; H03K 17/687; H03K 17/0812; H01L 29/66; G05F 3/16; G05F 1/56

(52) U.S. Cl. CPC H03K 17/567; H03K 17/687; H03K 17/08122; H01L 29/66462; G05F 3/16; G05F 1/56

(57) ABSTRACT

A power switch circuit includes an internal node; a first field-effect transistor including a first drain, a first gate and a first source; a second field-effect transistor including a second drain, a second gate and a second source, wherein the first drain is coupled to a voltage supply terminal, the first gate is coupled to the second source, the first source and the second drain are coupled to the internal node, and the second source is coupled to a ground; and a regulating circuit is coupled to the internal node, wherein the regulating circuit is configured to regulate a voltage value of the internal node after the power switch circuit is activated.

### CROSS REFERENCE TO RELATED APPLICATIONS

This application claims the benefit of U.S. provisional application No. 63/156,905 filed on 2021 Mar. 4, included herein by reference in its entirety.

### BACKGROUND OF THE INVENTION

### 1. Field of the Invention

The present invention relates to a power switch circuit, and more particularly, to a power switch circuit with a cascode structure composed of a D-mode Gallium Nitride high electron mobility transistor and n-type metal oxide semiconductor field-effect transistor.

### 2. Description of the Prior Art

III-V semiconductors due to their characteristics may be applied to many types of integrated circuit device, such as high power transistors, high voltage transistors, high frequency transistors or high electron mobility transistors (HEMT). In recent years, the Gallium Nitride (GaN) series of materials have been widely used in high power and high frequency products due to their wide energy gaps and high saturation rates.

However, D-mode (Depletion-mode) Gallium Nitride high electron mobility transistor (GaN-HEMT) is difficult to be directly used as a power switch because of its normally on characteristic. Therefore, how to effectively use the characteristics of D-mode GaN-HEMT while avoiding the problems caused by its normally on characteristics has become one of the goals in the industry.

### SUMMARY OF THE INVENTION

The purpose of the present invention is to provide a power switch circuit to regulate the voltage of internal node to avoid damage to the power switch circuit.

The present invention provides a power switch circuit, comprising an internal node; a first field-effect transistor, comprising a first drain, a first gate and a first source; a second field-effect transistor, comprising a second drain, a second gate and a second source, wherein the first drain is coupled to a voltage supply terminal, the first gate is coupled to the second source, the first source and the second drain are coupled to the internal node, and the second source is coupled to a ground; and a regulating circuit, coupled to the internal node, configured to regulate a voltage value of the internal node after the power switch circuit is activated.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a power switch circuit with a conventional cascode structure.

FIG. 2 is a schematic diagram of a power switch circuit according to an embodiment of the present invention.

FIG. 3 is a schematic diagram of a regulating circuit according to an embodiment of the present invention.

FIG. 4 is a schematic diagram of the voltages of the internal node and the high voltage terminal of a power switch circuit according to an embodiment of the present invention.

FIG. 5 is a schematic diagram of the voltages of the internal node and the high voltage terminal of a power switch circuit according to another embodiment of the present invention.

### DETAILED DESCRIPTION

Certain terms are used throughout the description and following claims to refer to particular components. As one skilled in the art will appreciate, hardware manufacturers may refer to a component by different names. This document does not intend to distinguish between components that differ in name but not function. In the following description and in the claims, the terms “include” and “comprise” are utilized in an open-ended fashion, and thus should be interpreted to mean “include, but not limited to”. Also, the term “couple” is intended to mean either an indirect or direct electrical connection. Accordingly, if one device is coupled to another device, that connection may be through a direct electrical connection, or through an indirect electrical connection via other devices and connections.

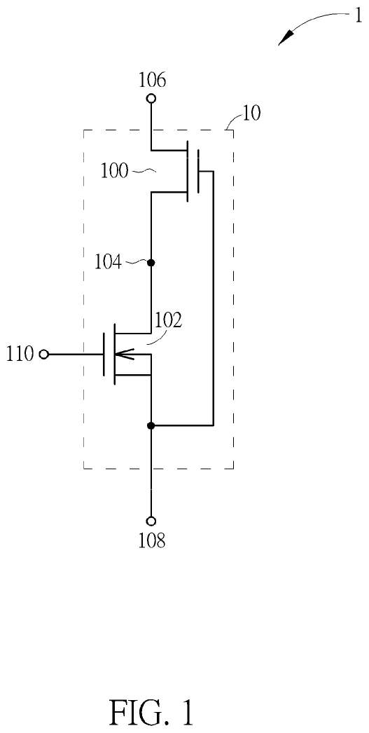

Please refer to FIG. 1. FIG. 1 is a schematic diagram of a power switch circuit 1 with a conventional cascode structure. The power switch circuit 1 includes a first field-effect transistor (FET) 100 and a second FET 102, which are a D-mode Gallium Nitride high electron mobility transistor (GaN-HEMT) and an n-type metal oxide semiconductor field-effect transistor (MOSFET) respectively, and are packaged in a first packaging module 10. The source of the D-mode GaN-HEMT 100 and the drain of the n-type MOSFET 102 are coupled to an internal node 104. The gate of the D-mode GaN-HEMT 100 is coupled to the source of the n-type MOSFET 102. The first packaging module 10 includes a high voltage terminal 106, a low voltage terminal 108 and a control terminal 110, which are coupled to the drain of the D-mode GaN-HEMT 100, the gate of the n-type MOSFET 102 and the source of the n-type MOSFET 102 respectively. In an embodiment, the high voltage terminal 106 is coupled to a high voltage power supply, and the low voltage terminal is coupled to ground voltage GND or a current sensing device. It should be noted that another end of the current sensing device is coupled to a ground voltage GND. The control terminal 110 receives a control signal to control the operation of the power switch circuit 1. When the D-mode GaN-HEMT 100 and the n-type MOSFET 102 are in the switching process to turn off and the high-voltage power supply voltage received by the high voltage terminal 106 is caused by the interaction of the parasitic capacitances of the D-mode GaN-HEMT 100 and the n-type MOSFET 102, the internal node 104 may have abnormally high voltage. On the other hand, when both the D-mode GaN-HEMT 100 and the n-type MOSFET 102 are turned off and the high voltage power supply voltage received by the high voltage terminal 106 rises, the internal node 104 may have an abnormally high voltage, which may cause an over-voltage problem to the internal node 104. For example, the drain to source voltage V_{DS} of the n-type MOSFET 102 may be too large and cause a hard breakdown. On the other hand, the gate to source voltage V_{GS} of the D-mode GaN-HEMT 100 may exceed an absolute rated voltage and cause the gate to collapse. Therefore, the over-voltage problem of the internal node 104 may make the power switch circuit 1 unable to work normally under a rated voltage and a rated power.

In order to improve the shortcomings of the power switch circuit 1, the present invention uses shaping and rectification to reduce the voltage of the internal node 104.

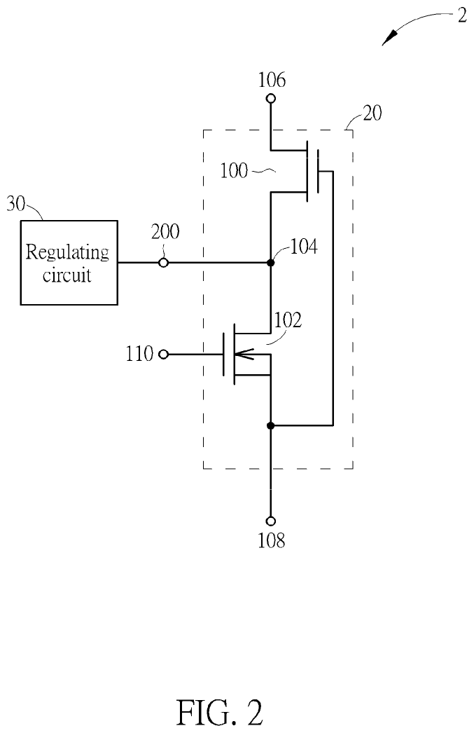

In detail, please refer to FIG. 2. FIG. 2 is a schematic diagram of a power switch circuit 2 according to an embodiment of the present invention. The power switch circuit 2 is derived from the power switch circuit 1, so the same components are denoted by the same symbols. The difference between the power switch circuit 1 and the power switch circuit 2 is that the D-mode GaN-HEMT 100 and the n-type MOSFET 102 of the power switch circuit 2 are packaged in a second packaging module 20. Compared with the first packaging module 10, the internal node 104 of the second packaging module 20 and a regulating circuit 30 are coupled via a regulating terminal 200. The regulating circuit 30 may regulate the voltage of the internal node 104 through the regulating terminal 200 to ensure that the power switch circuit 2 may operate normally.

Specifically, for the power switch circuit 2, when the D-mode GaN-HEMT 100 and the n-type MOSFET 102 are in the switching process to turn off or when both the D-mode GaN-HEMT 100 and the n-type MOSFET 102 are turned off, and the high voltage power supply voltage received by the high voltage terminal 106 rises, the regulating circuit 30 may regulate the voltage of the internal node 104. For example, the regulating circuit 30 uses shaping and rectification to reduce the voltage of the internal node 104. Thus, the regulating circuit 30 may prevent the internal node 104 from being abnormally high when the D-mode GaN-HEMT 100 and the n-type MOSFET 102 are in the switching process to turn off or when the D-mode GaN-HEMT 100 and the n-type MOSFET 102 are turned off, and the high voltage power supply voltage received by the high voltage terminal 106 rises. In an embodiment, the D-mode GaN-HEMT 100 and the n-type MOSFET 102 may also be separately packaging modules and form the power switch circuit 2. The operation of the power switch circuit 2 will not be repeated here. In another embodiment, the power switch circuit 2 may also be composed of D-mode GaN-HEMT and an e-type GaN-HEMT, or n-type MOSFET and n-type MOSFET. The operation of the power switch circuit 2 will not be repeated here.

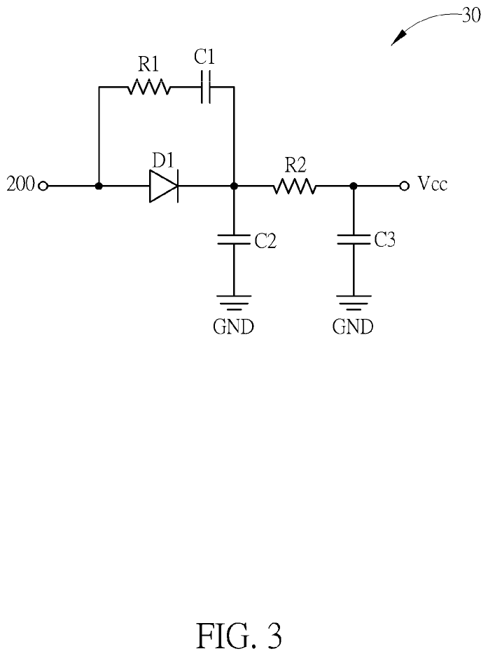

It should be noted that any circuit that may regulate the voltage of the internal node 104 in a timely manner described above and recycle the reflected voltage as energy may be used to implement the regulating circuit 30. For example, please refer to FIG. 3. FIG. 3 is a schematic diagram of an embodiment of the regulating circuit 30 shown in FIG. 2. In the embodiment, the regulating circuit 30 includes a diode Dl, resistors R1, R2 and capacitors C1, C2, C3. The capacitors C1, C2, a cathode of the diode Dl and the resistor R2 are coupled to a regulating node N. The capacitor C1 is coupled to the resistor R1. The resistor R2 and the capacitor C3 are coupled to a voltage common collector Vcc. The capacitors C2, C3 are coupled to the ground. The resistor R1 and the anode of the diode Dl are coupled to the regulating terminal 200. In detail, when the D-mode GaN-HEMT 100 and the n-type MOSFET 102 are in the switching process to turn off or when both the D-mode GaN-HEMT 100 and the n-type MOSFET 102 are turned off and the high voltage power supply voltage received by the high voltage terminal 106 rises, the regulating circuit 30 regulates the voltage of the internal node 104 through the regulating terminal 200 to prevent the drain to source voltage V_{DS} of the n-type MOSFET 102 being too high and causing hard breakdown, or the gate to source voltage V_{GS} of the D-mode GaN-HEMT 100 exceeding the absolute rated voltage and causing the gate to collapse. In an embodiment, when the high voltage power supply voltage received by the high voltage terminal 106 changes rapidly and is caused by the interaction of the parasitic capacitances of the D-mode GaN-HEMT 100 and the n-type MOSFET 102, which causes a DC or an AC component of the voltage of the internal node 104 to be higher than the voltage of the voltage common collector Vcc, the regulating circuit 30 regulates the voltage of the internal node 104 by shaping or rectification. In other words, the regulating circuit 30 clamps the voltage of the internal node 104. Furthermore, the regulating circuit 30 may also charge the voltage common collector Vcc simultaneously when the voltage of the internal node 104 is clamped. Thus, the energy consumed by the power switch circuit 1 in the unregulated voltage of the internal node 104 is recycled, and the efficiency of the power switch circuit 2 is improved.

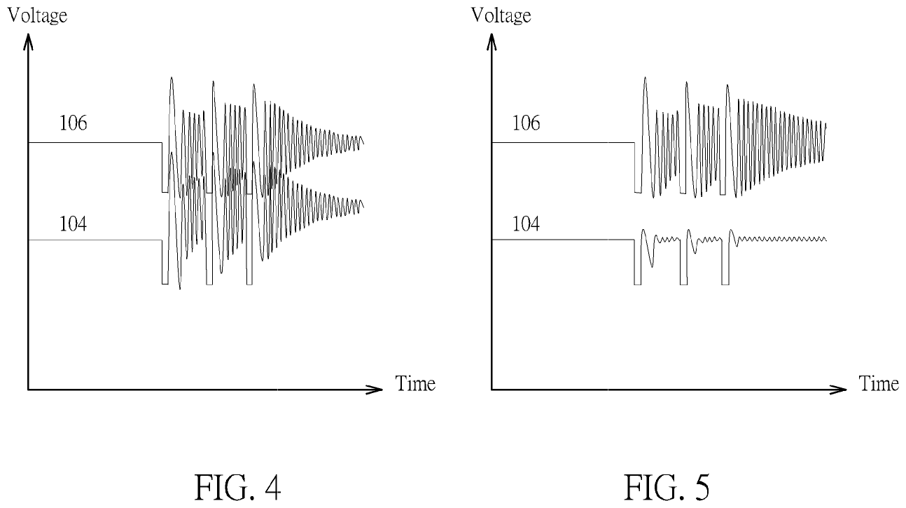

Specifically, please refer to FIGS. 4-5. FIG. 4 is a schematic diagram of voltages of the internal node 104 and the high voltage terminal 106 when the power switch circuit 1 does not regulate the voltage of the internal node 104 through the regulating terminal 200. When the high voltage power supply voltage received by the high voltage terminal 106 rises, the internal node 104 may have the abnormally high voltage, which may cause an over-voltage problem of the internal node 104. For example, the drain to source voltage V_{DS} of the n-type MOSFET 102 is too large and causes a hard breakdown. On the other hand, the gate to source voltage V_{GS} of the D-mode GaN-HEMT 100 exceeding an absolute rated voltage may cause the gate to collapse. FIG. 5 is a diagram of the voltages of the internal node 104 and the high voltage terminal 106 when the power switch circuit 2 regulates the internal node 104 through the regulating terminal 200. When the high voltage power supply voltage received by the high voltage terminal 106 rises, the voltage of the internal node 104 may not follow the high voltage power supply voltage as shown in FIG. 4 to generate the abnormally high voltage. Therefore, the hard breakdown of the n-type MOSFET 102 or the collapse of the gate of the D-mode GaN-HEMT 100 is avoided.

In summary, in the embodiment of the present invention, the voltage of the internal node of the power switch circuit is regulated by the regulating circuit, so that the voltage of the internal node is within a proper range when the power switch circuit is activated. Therefore, the power switch circuit may work normally under the rated voltage and rated power, so that the energy loss of the power switch circuit is reduced and the efficiency of the power switch circuit is improved. In the power switch circuit of the cascode structure composed of D-mode GaN-HEMT and n-type MOSFET, the present invention utilizes the regulating circuit to regulate the internal node of the power switch circuit, which also reduces the difficulty of matching D-mode GaN-HEMT and n-type MOSFET.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A power switch circuit, comprising:
an internal node;
a first field-effect transistor, comprising a first drain, a first gate and a first source;
a second field-effect transistor, comprising a second drain, a second gate and a second source, wherein the first drain is coupled to a voltage supply terminal, the first gate is coupled to the second source, the first source and the second drain are coupled to the internal node, and the second source is coupled to a ground; and
a regulating circuit, coupled to the internal node, configured to regulate a voltage value of the internal node after the power switch circuit is activated.

2. The power switch circuit of claim 1, wherein the first field-effect transistor and the second field-effect transistor are packaged in a module.

3. The power switch circuit of claim 1, wherein the regulating circuit is coupled to a voltage common collector (VCC), configured to reduce the voltage of the internal node through shaping and rectification, and charge the voltage common collector simultaneously.

4. The power switch circuit of claim 3, wherein the regulating circuit comprises:
a regulating terminal, coupled to the internal node;
a power source terminal, coupled to the voltage common collector;
a ground terminal, coupled between the second source and the ground;
a regulating node;
a first resistor, having one end coupled to the regulating terminal;
a diode, having an anode coupled to the regulating terminal, and a cathode coupled to the regulating node;
a first capacitor, coupled between another end of the first resistor and the regulating node;
a second capacitor, coupled between the regulating node and the ground terminal;
a second resistor, coupled between the regulating node and the ground terminal; and
a third capacitor, coupled between the power source terminal and the ground terminal.

5. The power switch circuit of claim 1, wherein the first field-effect transistor is a Depletion-mode Gallium Nitride high electron mobility transistor.

6. The power switch circuit of claim 1, wherein the second field-effect transistor is a low voltage n-type metal oxide semiconductor field-effect transistor.

7. The power switch circuit of claim 1, wherein the power source terminal provides a high voltage.
